(19) United States
(12) Patent Application Publication
(10) Pub. No.: US 2013/0276707 A1
(43) Pub. Date: Oct. 24, 2013

(54) VERTICAL FURNACE WITH CIRCUMFERENTIALLY DISTRIBUTED GAS INLET SYSTEM

(71) Applicant: Dieter Pierreux, Almere (NL)

(72) Inventor: Dieter Pierreux, Almere (NL)

(73) Assignee: ASM IP Holding B.V., Almere (NL)

(21) Appl. No.: 13/453,402

(22) Filed: Apr. 23, 2012

(51) Int. Cl. C23C 16/458

(52) U.S. Cl. 118/728

(57) ABSTRACT

A vertical furnace comprises a substantially cylindrical process tube vertically extending and delimiting a reaction space; a boat for accommodating a plurality of substrates to be vertically spaced apart from each other; a gas inlet system comprising a plurality of distribution tubes disposed at a circumference of the reaction space, wherein each of the distribution tubes have a plurality of gas injection holes distributed over a length of the distribution tubes and the distribution tubes are symmetrically disposed along an entire circumference of the reaction space; and at least one reaction gas source connected to the gas inlet system.

### BACKGROUND OF THE INVENTION

(a) Field of the Invention

The present invention relates to a vertical furnace and more in particular to a gas inlet system in a vertical furnace.

(b) Description of the Related Art

In vertical furnaces, a stack of vertically spaced substrates, such as semiconductor wafers, can be processed. E.g. a film can be grown on the substrates by Chemical Vapor Deposition (CVD). Such a furnace is described in U.S. Pat. No. 5,252,133.

A vertical furnace comprises a process tube delimiting a reaction space and having a collar at its lower end, flanges supporting the process tube, a door delimiting the reaction space at the lower end of the process tube, a pedestal supported by the door, a boat which is disposed on the pedestal and in which vertically spaced substrates are accommodated, and a vertically extending gas inlet tube. The gas inlet tube has a plurality of vertically spaced injection holes in order to distribute a reaction gas over a substantial height of the stack of the substrates to avoid depletion effects over the stack and to achieve a uniform process result, e.g. a uniform film thickness. Gas is removed from the reaction space through an exhaust opening, which may be connected to a vacuum pump.

A disadvantage of this method is that the uniformity of the process over a substrate might be poor as the film thickness is typically relatively thicker at the side of the substrate facing the gas inlet tube and relatively thin at the opposing side of the substrate. This uniformity problem can be overcome by rotating the boat holding the substrates during processing. However, in case of processes using repeated pulses of reaction gases like Atomic Layer Deposition (ALD) or other pulsed processes, the pulse time might be so short that, at workable boat rotation speeds, the boat cannot make one full revolution during the pulse time. Although, in ALD processes, the pulse times can be chosen so long as to reach absorption of a full and uniform monolayer of reaction gas on the entire surface by a self-limited absorption process, this would result in long process times and make the process inefficient. Furthermore, other pulsed processes which do not exhibit a self-limited growth and for which a uniform process result is desirable might be operated in the furnace. The boat rotation speed is relatively slow in these vertical furnaces such that 1 to 3 revolutions can be made during 1 minute. Therefore, for processes with short pulse time, the boat rotation speed cannot be adapted because a full revolution cannot be made during one pulse time.

### SUMMARY OF THE INVENTION

According to an aspect of the present invention, a vertical furnace comprises a substantially cylindrical process tube extending in a vertical direction and delimiting a reaction space; a boat for accommodating a plurality of substrates that are vertically spaced apart from each other; a first gas inlet system comprising a plurality of distribution tubes disposed at a circumference of the reaction space, wherein each of the distribution tubes have a plurality of gas injection holes distributed over a length of the distribution tubes and the distribution tubes are symmetrically disposed along an entire circumference of the reaction space; and at least one reaction gas source connected to the first gas inlet system.

According to another aspect of the present invention, a vertical furnace comprises a substantially cylindrical process tube extending in a vertical direction and delimiting a reaction space; a boat for accommodating a plurality of substrates that are vertically spaced apart from each other; a gas inlet system comprising at least one distribution tube disposed at a circumference of the reaction space, wherein the at least one distribution tube has a plurality of gas injection holes that are distributed over a length of the at least one distribution tube and distributed regularly along an entire circumference of the reaction space; and a reaction gas source connected to the gas inlet system.

### BRIEF DESCRIPTION OF THE DRAWINGS

FIG. 1A is a cross-sectional side view of a vertical furnace in accordance with an embodiment of the present invention.

FIG. 1B is a cross-sectional top view of a vertical furnace in accordance with the embodiment of FIG. 1A.

FIGS. 2 to 6 are cross-sectional top views of vertical furnaces in accordance with other embodiments of the present invention.

FIGS. 7 and 8 are cross-sectional side views of vertical furnaces in accordance with other embodiments of the present invention.

### DETAILED DESCRIPTION OF THE EMBODIMENTS

Advantages and features of the present invention and methods to achieve them will be elucidated from exemplary embodiments described below in detail with reference to the accompanying drawings. However, the present invention is not limited to exemplary embodiment disclosed herein but may be implemented in various forms. The exemplary embodiments are provided by way of example only so that a person of ordinary skill in the art can fully understand the disclosures of the present invention and the scope of the present invention. Therefore, the present invention will be defined only by the scope of the appended claims.

A vertical furnace with circumferentially distributed gas inlet system according to an exemplary embodiment of the present invention will now be described with reference to accompanying drawings.

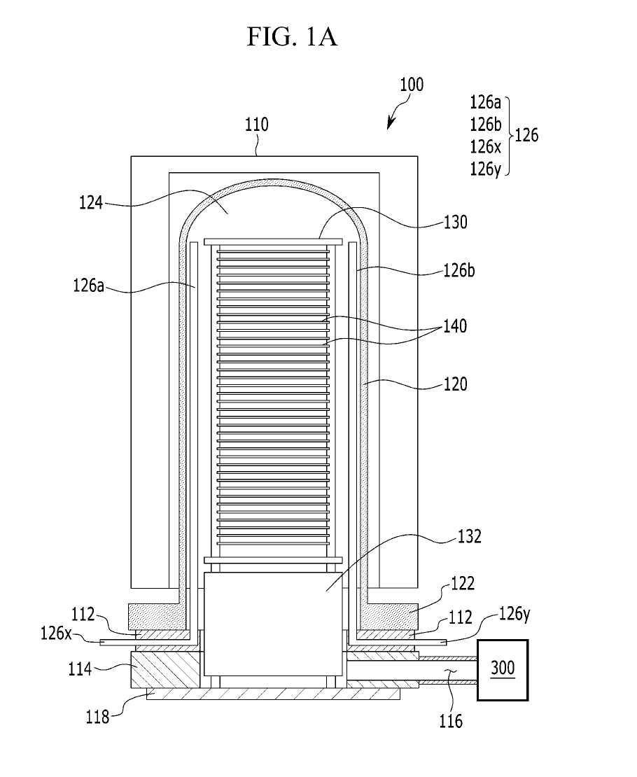

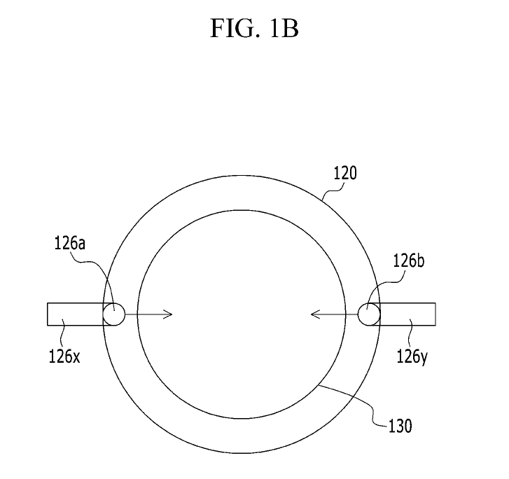

FIG. 1A is a cross-sectional side view of a vertical furnace in accordance with an embodiment of the present invention and FIG. 1B is a cross-sectional top view of a vertical furnace in accordance with the embodiment of FIG. 1A.

The furnace system is indicated in its entirety by the reference numeral 100. The furnace system 100 comprises a heating element 110, a vertically extending process tube 120, flanges 112 and 114, a door 118, a boat 130, a pedestal 132, an exhaust opening 116, and a gas inlet system 126.

The process tube 120, delimiting a reaction space 124, is provided at its lower end with a collar 122 and is disposed on and supported by the flanges 112 and 114. At a lower end of the process tube 120, the reaction space 124 is delimited by the door 118. The door 118 supports the pedestal 132 on which the boat 130 is placed. The boat 130 accommodates a stack of substrates 140 which are vertically spaced apart. The majority or all of these substrates 140 are objects of manufacturing process, although, at the upper and lower ends of the boat 130, some dummy substrates may be accommodated. The substrates 140 may be semiconductor wafers in a circular shape. However, the substrates 140 may alternatively be made of other materials such as glass or sapphire and may have other shapes such as rectangular or square. The gas inlet system 126 comprises distribution tubes 126a and 126b extending in a vertical direction and inlet tubes 126x and 126y extending in a horizontal direction. The distribution tubes 126a and 126b are respectively connected to the inlet tubes 126x and 126y and have a plurality of injection holes to distribute a reaction gas over a substantial height of the stack of substrates 140. The injection holes may be disposed along the distribution tubes 126a and 126b with a uniform distance or varying distance. The gas injection holes are distributed over a substantial part of the height of the batch of the substrates 140 in the boat 130, preferably over 50% or more of the height or more preferably over substantially the entire height of the batch of the substrates 140. The distribution tubes 126a and 126b are disposed at opposite sides of the reaction space 124. The reaction gas is injected through the inlets of the inlet tubes 126x and 126y and is sprayed out through the injection holes of the distribution tubes 126a and 126b to avoid depletion effects over the stack and to achieve a uniform process result, e.g. a uniform film thickness. The inlet tubes 126x and 126y are connected to the same source of reaction gas, not shown. Exhaust gas is removed from the reaction space 124 through the exhaust opening 116, which may be connected to a vacuum pump 300.

The vertical furnace according to the embodiment of FIGS. 1A and 1B may produce a uniform process result over each substrate 140 without rotating the substrate 140. However, to enhance uniformity of the process result, the boat 130 may be rotated.

In the embodiment of FIGS. 1A and 1B, the gas inlet system 126 comprises two vertical tubes 126a and 126b having a plurality of injection holes extending over a substantial part of the height of the stack of substrates 140. However, the gas inlet system 126 may comprise three or more distribution tubes.

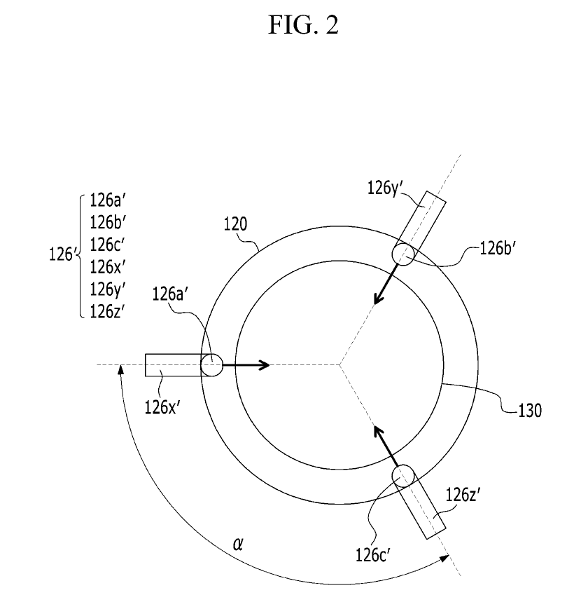

FIG. 2 is a cross-sectional top view of a vertical furnace in accordance with another embodiment of the present invention.

In the embodiment of FIG. 2, the vertical furnace comprises a gas inlet system 126′ having three distribution tubes 126a′, 126b′, and 126c′ and three inlet tubes 126x′, 126y′, and 126z′. The distribution tubes 126a′, 126b′, and 126c′ are respectively connected to the inlet tubes 126x′, 126y′, and 126z′ and have a plurality of injection holes to distribute a reaction gas over a substantial height of the stack of substrates. The injection holes may be disposed along the distribution tubes 126a′, 126b′, and 126c′ with a uniform distance or varying distance. The gas injection holes are distributed over a substantial part of the height of the batch of the process substrates in the boat, preferably over 50% or more of the height or more preferably over substantially the entire height of the batch of the process substrates. The distribution tubes 126a′, 126b′, and 126c′ are symmetrically disposed along the circumference of the reaction space 124. Accordingly, in a cross-sectional plane, an angle α formed between lines through a heart of the distribution tubes 126a′, 126b′, and 126c′ and the center axis of the reaction space 124 is 120 degrees. The inlet tubes 126x′, 126y′, and 126z′ may be connected to the same source of reaction gas or different sources of reaction gases.

The vertical furnace according to the embodiment of FIG. 2 may produce a uniform process result over each substrate 140 without rotating the substrate 140. However, to enhance uniformity of the process result, the boat 130 may be rotated.

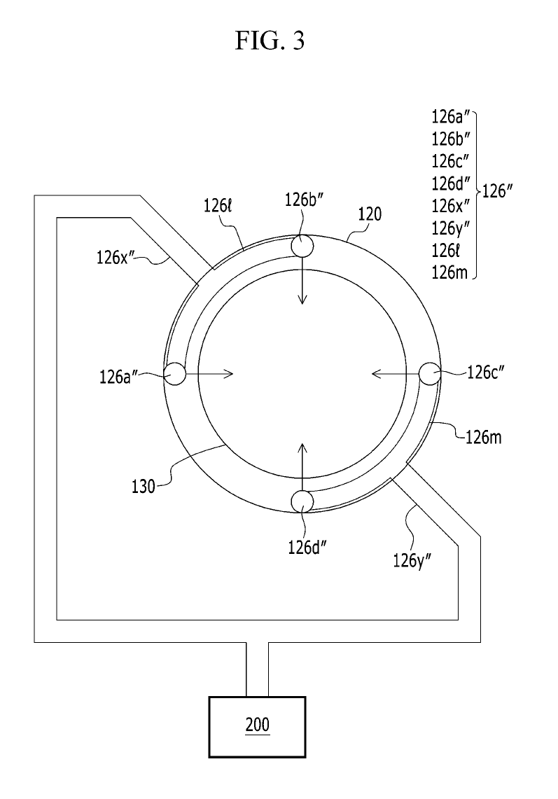

FIG. 3 is a cross-sectional top view of a vertical furnace in accordance with another embodiment of the present invention.

In the embodiment of FIG. 3, the vertical furnace comprises a gas inlet system 126″ having four distribution tubes 126a″, 126b″, 126c″, and 126d″, two inlet tubes 126x″ and 126y″, and two connection tubes 126l and 126m. The distribution tubes 126a″ and 126b″ are connected to both ends of the connection tube 1261 and the distribution tubes 126c″ and 126d″ are connected to both ends of the connection tube 126m. The inlet tubes 126x″ and 126y″ are respectively connected to mid portions of the connection tubes 126l and 126m. The distribution tubes 126a″, 126b″, 126c″, and 126d″ have a plurality of injection holes to distribute a reaction gas over a substantial height of the stack of substrates. The injection holes may be disposed along the distribution tubes 126a″, 126b″, 126c″, and 126d″ with a uniform distance or varying distance. The gas injection holes are distributed over a substantial part of the height of the batch of the process substrates in the boat, preferably over 50% or more of the height or more preferably over substantially the entire height of the batch of the process substrates. The distribution tubes 126a″, 126b″, 126c″, and 126d″ are rotational-symmetrically disposed along the circumference of the reaction space 124 wherein the center axis of the reaction space is the axis of rotation. Accordingly, in a cross-sectional plane, an angle formed between lines through the heart of the distribution tubes 126a″, 126b″, 126c″, and 126d″ and the center axis of the reaction space 124 is 90 degrees. The reaction gas is injected through the inlets of the inlet tubes 126x″ and 126y″, distributed to the distribution tubes 126a″, 126b″, 126c″, and 126d″ through the connection tubes 126l and 126m, and sprayed out through the injection holes of the distribution tubes 126a″, 126b″, 126c″, and 126d″. The inlet tubes 126x″ and 126y″ are connected to the same source 200 of reaction gas.

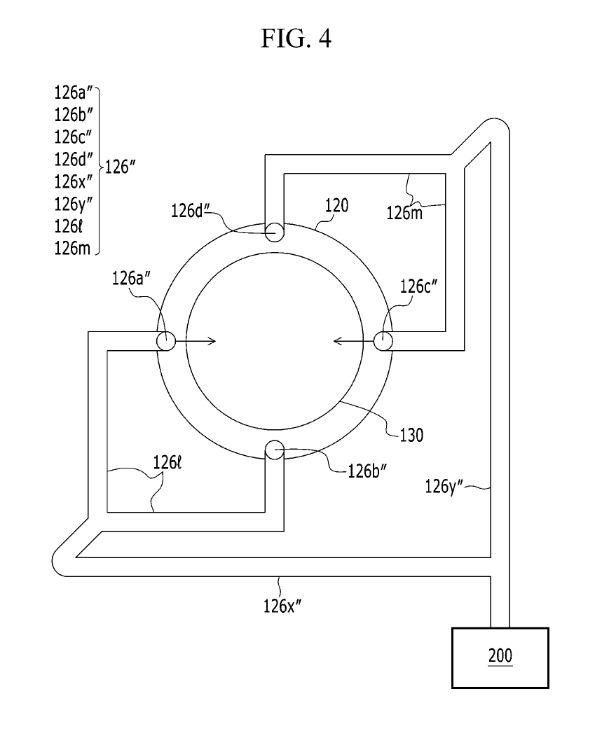

In another embodiment, as illustrated in FIG. 4, connection tubes 126l and 126m may be disposed outside of the process tube 120.

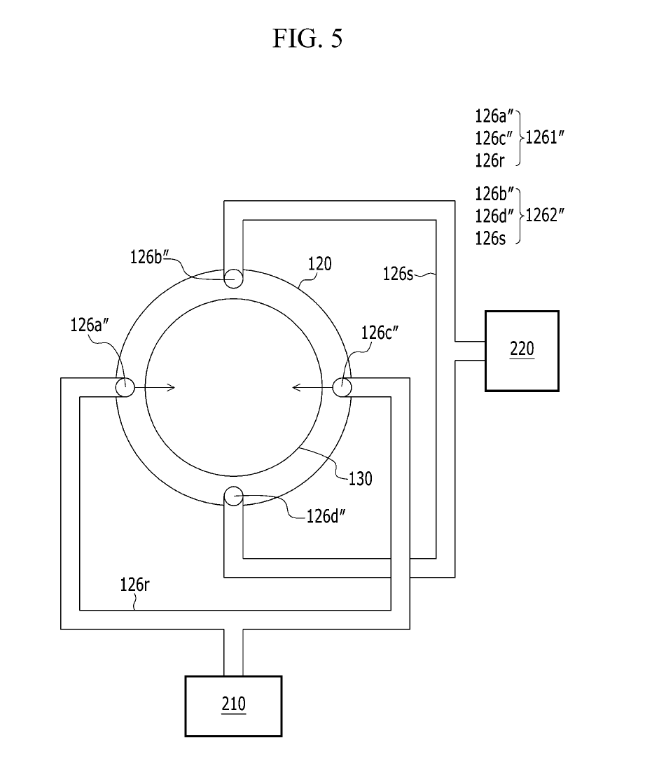

In another embodiment, as illustrated in FIG. 5, a vertical furnace may comprise two separate gas inlet systems 1261″ and 1262″ which are respectively connected to different gas sources 210 and 220. The first gas inlet system 1261″ comprises two distribution tubes 126a″ and 126c″ which are disposed at opposite sides of the reaction space 124 and a connection tube 126r which is connected to the first gas source 210. The second gas inlet system 1262″ comprises two distribution tubes 126b″ and 126d″ which are disposed at opposite sides of the reaction space 124 and a connection tube 126s which is connected to the second gas source 220. The positions of the two gas inlet systems relative to each other differ by an angle of rotation of 90 degrees. The first gas inlet system 1261″ and the second gas inlet systems 1262″ may be separately operated. Accordingly, the first gas of the first gas source 210 and the second gas of the second gas source 220 may be injected simultaneously, as in regular Chemical Vapor deposition (CVD) or sequentially, as in Atomic Layer Deposition (ALD), or separately with a purge.

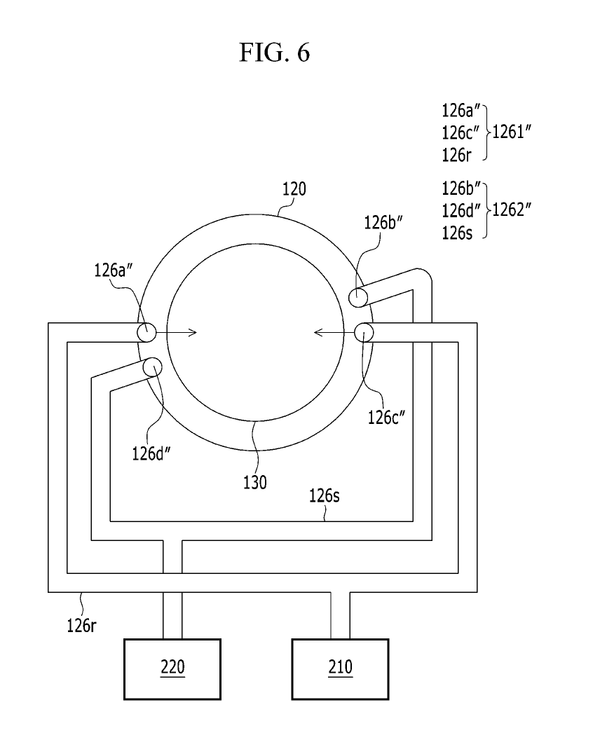

In another embodiment, as illustrated in FIG. 6two distribution tubes 126a″ and 126c″ of a first gas inlet system 1261″ may be disposed at opposite sides of the reaction space 124 and two distribution tubes 126b″ and 126d″ of a second gas inlet system 1262″ may be disposed at opposite sides of the reaction space 124, whereas the two gas inlet systems are adjacent to each other and their positions relative to each other differ by an angle of rotation that is less than 90 degrees.

The vertical furnaces according to the embodiments of FIGS. 3 to 6 may produce a uniform process result over each substrate 140 without rotating the substrate 140. However, to enhance uniformity of the process result, the boat 130 may be rotated. The distribution tubes of the embodiments of FIGS. 1A, 1B, and 2 may be connected to each other through a connection tube which is connected to an inlet tube.

In the previous embodiments, the distribution tubes extend in the vertical direction. However, the distribution tubes may be disposed to extend in a slanted direction with respect to the vertical direction or to extend along a spiral pass.

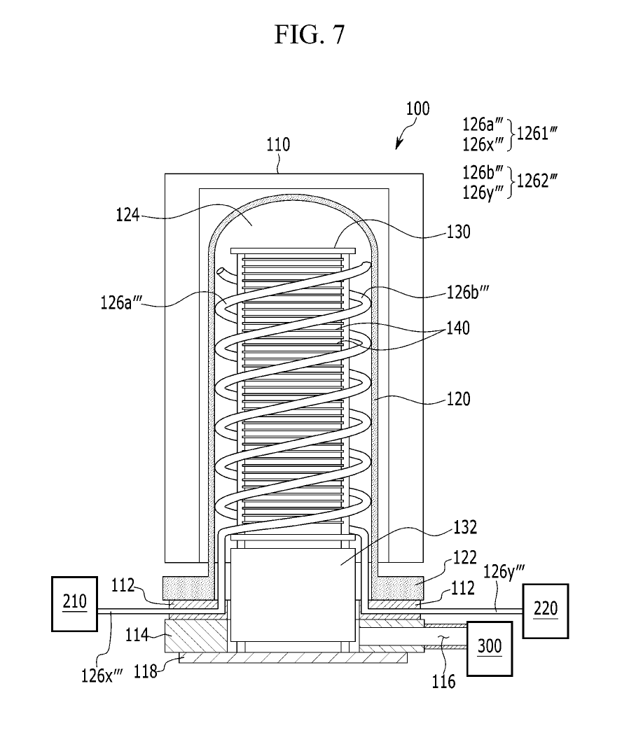

FIG. 7 is a cross-sectional side view of a vertical furnace in accordance with another embodiment of the present invention.

According to the embodiment of FIG. 7, the vertical furnace comprises two gas inlet systems 1261′″ and 1262′″ having distribution tubes 126a′″ and 126b′″ and inlet tubes 126x′″ and 126y′″. The distribution tubes 126a′″ and 126b′″ respectively extend along respective spiral passes which are disposed at circumference of the reaction space 124. The axis of the spiral passes coincides with the axis of the process tube 120 and the spirals of the distribution tubes 126a′″ and 126b′″ respectively make one full revolution or more. The spirals of the distribution tubes 126a′″ and 126b′″ may have n revolutions, where n is an integer in a range from 1 to 20, preferably in a range from 3 to 10. The distribution tubes 126a′″ and 126b′″ are symmetrically disposed along the circumference of the reaction space. The distribution tubes 126a′″ and 126b′″ respectively have a plurality of gas injection holes distributed over the length of the distribution tubes 126a′″ and 126b′″ with a uniform distance or varying distance. The gas injection holes are distributed over a substantial part of the height of the batch of the process substrates 140 in the boat 130, preferably over 50% or more of the height, or more preferably over substantially the entire height of the batch of the process substrates 140.

The vertical furnace according to the embodiment of FIG. 7 may produce a uniform process result over each substrate 140 without rotating the substrate 140. However, to enhance uniformity of the process result, the boat 130 may be rotated.

In the embodiment of FIG. 7, the first gas inlet system 1261′″ has the distribution tube 126a′″ and the inlet tube 126x′″ and the second gas inlet system 1262′″ has the distribution tube 126b′″ and the inlet tube 126y′″. The inlet tubes 126x′″ and 126y′″ of the respective gas inlet systems 1261′″ and 1262′″ are connected to the different gas sources 210 and 220. In fact, each spiral tube forms a gas inlet system in accordance with an embodiment of the invention. However, one of the gas inlet systems may be omitted. On the other hand, a gas inlet system may comprise three or more spiral distribution tubes and/or inlet tubes. In any case, the gas injection holes may be regularly distributed along the entire circumference of the reaction space 124.

The gas inlet systems 1261′″ and 1262′″ may be used for injection of both or one of the first reaction gas and the second reaction gas. In this configuration, the two gas inlet systems 1261′″ and 1262′″ may be separately operated. Accordingly, the first and second reaction gases may be injected simultaneously, as in regular Chemical Vapor deposition (CVD) or sequentially, as in Atomic Layer Deposition (ALD), or separately with a purge. Separate gas inlet systems for different reaction gases may be desirable when the reaction gases are mutually very reactive.

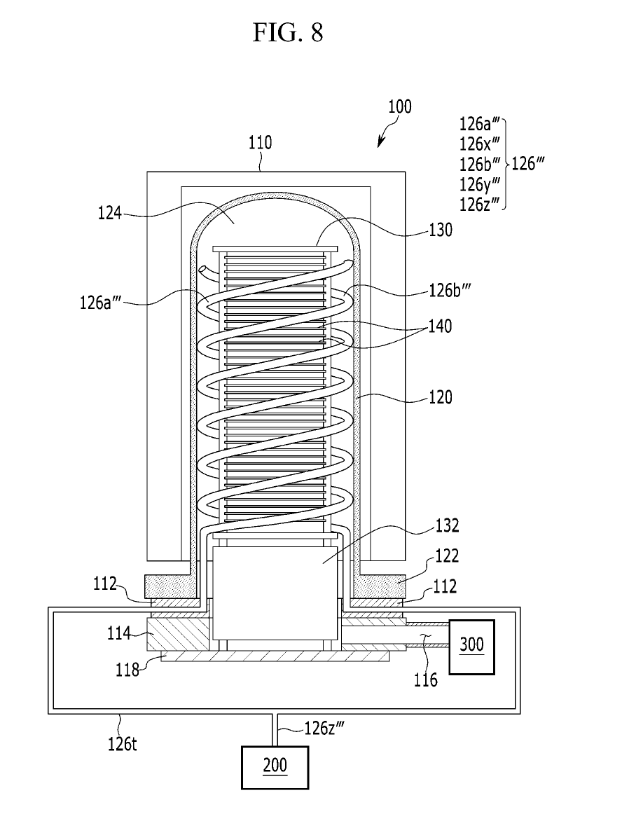

In another embodiment, as illustrated in FIG. 8, distribution tubes 126a′″ and 126b′″ may be connected to each other through a connection tube 126t which is connected to a common inlet tube 126z″ and the common inlet tube 126z″ being connected to a common gas source 200.

The vertical furnaces according to the embodiments of the present invention may produce a uniform process result over each substrate without rotating the substrate. The vertical furnaces according to the embodiments of the present invention may be appropriate for processes using short reaction gas pulses because those may produce a uniform process result independent of the duration of the pulses.

In case of multiple gas distribution tubes connected to a single gas source, the flow through each gas distribution tube may be controlled by controlling the total flow by a flow control device and controlling the flows through each gas distribution tube by controlling the restriction of the flow path to each gas distribution path. E.g. the flow paths to each gas distribution tube may be of equal length and shape, resulting in equal flows through each gas distribution tube. Alternatively, a flow control device may be provided for each individual gas distribution tube to control the flow.

It will be apparent to those skilled in the art that various modifications and variations can be made in the present invention without departing from the scope or spirit of the invention. Thus, it is intended that the present invention cover the modifications and variations of this invention provided that they come within the scope of the appended claims or their equivalents.

What is claimed is:

1. A vertical furnace comprising:
a substantially cylindrical process tube extending in a vertical direction and delimiting a reaction space;
a boat for accommodating a plurality of substrates that are vertically spaced apart from each other;
a first gas inlet system comprising a plurality of distribution tubes disposed at a circumference of the reaction space, wherein each of the distribution tubes have a plurality of gas injection holes distributed over a length of the distribution tubes and the distribution tubes are symmetrically disposed along an entire circumference of the reaction space; and
at least one reaction gas source connected to the first gas inlet system.

2. The vertical furnace of claim 1, wherein the distribution tubes extend in the vertical direction.

3. The vertical furnace of claim 1, wherein a number of the distribution tubes is two, wherein the distribution tubes are disposed at opposite sides of the reaction space.

4. The vertical furnace of claim 1, wherein a number of the distribution tubes is three or four.

5. The vertical furnace of claim 1, wherein the first gas inlet system further comprises a connection tube connecting at least two of the distribution tubes and an inlet tube connected to the connection tube.

6. The vertical furnace of claim 5, wherein all of the distribution tubes are connected to a same reaction gas source.

7. The vertical furnace of claim 1, wherein the reaction gas source comprises a first reaction gas source and a second reaction gas source respectively connected to each one of the distribution tubes.

8. The vertical furnace of claim 1, further comprising a second gas inlet system that comprises a plurality of distribution tubes disposed at a circumference of the reaction space, wherein each of the distribution tubes have a plurality of gas injection holes distributed over a length of the distribution tubes and the distribution tubes are symmetrically disposed along an entire circumference of the reaction space and wherein the first gas inlet system and the second gas inlet system are separately operated.

9. The vertical furnace of claim 8, wherein the reaction gas source comprises a first reaction gas source and a second reaction gas source respectively connected to the first gas inlet system and the second gas inlet system.

10. The vertical furnace of claim 9, wherein the first gas inlet system has two distribution tubes disposed at opposite sides of the reaction space and the second gas inlet system has two distribution tubes disposed at opposite sides of the reaction space.

11. The vertical furnace of claim 10, wherein the position of the distribution tubes of the first gas inlet system differ by the position of the distribution tubes of the second gas inlet system by an angle of rotation that less than 90 degrees.

12. The vertical furnace of claim 1, wherein the distribution tubes extend along a spiral pass.

13. The vertical furnace of claim 1, wherein the gas injection holes are distributed over 50% or more of a height of a batch of the substrates.

14. A vertical furnace comprising:
a substantially cylindrical process tube extending in a vertical direction and delimiting a reaction space;
a boat for accommodating a plurality of substrates that are vertically spaced apart from each other;
a gas inlet system comprising at least one distribution tube disposed at a circumference of the reaction space, wherein the at least one distribution tube has a plurality of gas injection holes that are distributed over a length of the at least one distribution tube and distributed regularly along an entire circumference of the reaction space; and
a reaction gas source connected to the gas inlet system.

15. The vertical furnace of claim 14, wherein the at least one distribution tube extends along a spiral pass.

16. The vertical furnace of claim 15, wherein a spiral of the at least one distribution tube makes n revolutions, where n is an integer in a range from 1 to 20.

17. The vertical furnace of claim 16, wherein n is an integer in a range from 3 to 10

18. The vertical furnace of claim 14, wherein the at least one distribution tube comprises a first distribution tube and a second distribution tube connected to the reaction gas source and extending along spiral passes.

19. The vertical furnace of claim 18, wherein the gas inlet system further comprises a connection tube connecting between the first distribution tubes and the second distribution tube and an inlet tube connected to the connection tube.
